(19) United States
(12) Patent Application Publication
(10) Pub. No.: US 2024/0347607 A1
(43) Pub. Date: Oct. 17, 2024

(54) SHIELDED GATE TRENCH DEVICES HAVING SHORT CHANNELS

(71) Applicant: Nami MOS CO., LTD., New Taipei City (TW)

(72) Inventors: FU-YUAN HSIEH, New Taipei City (TW); LIN XU, SHANGHAI (CN)

(73) Assignee: Nami MOS CO., LTD., New Taipei City (TW)

(21) Appl. No.: 18/135,485

(22) Filed: Apr. 17, 2023

(51) Int. Cl. H01L 29/40; H01L 29/06; H01L 29/78; H01L 29/872

(52) U.S. Cl. CPC H01L 29/407; H01L 29/0634; H01L 29/7813; H01L 29/8725

(57) ABSTRACT

A SGT MOSFET and a SGT super barrier rectifier having improved on-resistance and gate charge structures are disclosed in this invention by applying a short channel implant region for formation of a shorter channel length after body implantation and diffusion, and by introducing a super junction region below an oxide charge balance region for breakdown voltage enhancement. The present invention can further achieve a lower specific on-resistance by applying multiple stepped epitaxial layers or multiple stepped oxide structure.

### FIELD OF THE INVENTION

This invention relates generally to semiconductor devices, and more particularly, to shielded gate trench (SGT) MOSFETs (Metal Oxide Semiconductor Field Effect Transistor) and SGT super barrier rectifiers (SBRs) having short channels to achieve lower on-resistance and less switching loss.

### BACKGROUND OF THE INVENTION

Please refer to FIG. 1A and FIG. 1B of two conventional types of SGT MOSFET structures, compared with traditional single gate trench MOSFETs, the SGT MOSFETs illustrated in FIG. 1A and FIG. 1B are more attractive due to lower gate charge and on-resistance as results of the existence of oxide charge balance (OCB) region in drift region and thick oxide underneath gate electrode.

To further reduce the on-resistance, a new SGT structure with multiple stepped oxide (MSO) is disclosed in U.S. Pat. No. 9,716,009 as shown in FIG. 1C, with specific on-resistance about 25% lower than the SGT MOSFETs as shown in FIG. 1A and FIG. 1B. The MSO structure has multiple stepped oxide films and stepped single domain poly crystalline silicon field plate in the trench, by optimizing the length and width of the steps, the MSO structure can achieve a lower on-resistance at a same breakdown voltage as the conventional field plate MOSFET.

However, the above three prior arts still encounter high specific on-resistance and high gate charge issues as results of long channel length, which will result in low efficiency in synchronous rectifying applications.

Therefore, there is still a need in the art of the semiconductor device design and fabrication, particularly for SGT MOSFET design and fabrication, to provide a novel cell structure, device configuration and manufacturing process that making an SGT MOSFET have lower specific on-resistance, higher frequency and efficiency applications.

### SUMMARY OF THE INVENTION

The present invention discloses SGT MOSFETs, SGT super junction (SJ) MOSFETs, SGT SBRs and SGT SJ SBRs providing ways to reduce channel resistance, drift region resistance and gate charge by optimizing channel structure, and adding SJ regions under an oxide charge balance (OCB) region. The optimized channel structure is implemented by applying a short channel implant region surrounding each gate electrode to make the channel length shorter after body diffusion than prior arts, thus reducing the channel resistance of the device without degrading avalanche capability. The drift region resistance is significantly reduced by introducing multiple stepped epitaxial (MSE) structures and multiple stepped oxide (MSO) structures. Furthermore, a SJ region is introduced in some preferred embodiments above the substrate layer and below the OCB region to ensure that whole drift region is fully depleted and breakdown occurs at a middle of the adjacent trenched gates or the SJ region without having an early breakdown occurring at the channel regions for avalanche capability enhancement.

According to one aspect, the invention features a SGT device formed in an epitaxial layer of a first conductivity type onto a substrate of the first conductivity type, further comprising: a plurality of gate trenches surrounded by source regions of the first conductivity type encompassed in body regions of a second conductivity type near a top surface of the epitaxial layer, each of the gate trenches is filled with a gate electrode and a shielded gate electrode, wherein the shielded gate electrode is insulated from the epitaxial layer by a first insulating film, the gate electrode is insulated from the epitaxial layer by a gate oxide, the shielded gate electrode and the gate electrode is insulated from each other by an (Inter-Poly Oxide) IPO film, the gate oxide surrounds the gate electrode and has a less thickness than the first insulating film; the body regions, the shielded gate electrode and the source regions are shorted together to a source metal through a plurality of trenched contacts; an OCB region is formed between two adjacent gate trenches; and a short channel implant region is formed along upper sidewalls of the gate trenches and surrounds the gate electrode.

According to another aspect, in some preferred embodiments, the epitaxial layer is a single epitaxial layer with a uniform doping concentration. In some other preferred embodiments, the epitaxial layer has MSE layers comprising at least two stepped epitaxial layers of different doping concentrations decreasing stepwise in a direction from substrate to a top surface of the epitaxial layer, wherein each of the MSE layers has a uniform doping concentration as grown.

According to another aspect, in some preferred embodiments, the gate electrode is not electrically shorted together to a source metal, the SGT device is a MOSFET having a gate electrode, a source electrode and a drain electrode. In some other preferred embodiments, the gate electrode is electrically shorted together to a source metal; the SGT device is a super barrier rectifier (SBR) having an anode electrode and a cathode electrode, wherein the source region is electrically connected with the anode electrode and the drain region is electrically connected with the cathode electrode.

According to another aspect, in some preferred embodiments, the gate electrode is disposed above the shielded gate electrode. In some other preferred embodiments, the shielded electrode is disposed in the middle and the gate electrode is disposed surrounding upper portion of the shielded electrode.

According to another aspect, in some preferred embodiments, the upper portion of the shielded gate electrode is fully oxidized as a second insulating film during growing a gate oxide.

According to another aspect, in some preferred embodiments, the first insulating film is a single oxide film having a uniform thickness along sidewalls of the gate trenches. In some other preferred embodiments, the first insulating film has a MSO structure with thickness decreasing stepwise in a direction from substrate to the body regions.

According to another aspect, the present invention also features a SGT SJ device formed in an epitaxial layer of a first conductivity type onto a substrate of the first conductivity type, further comprising: a plurality of gate trenches formed in an active area, surrounded by source regions of the first conductivity type encompassed in body regions of a second conductivity type near a top surface of the epitaxial layer, each of the gate trenches is filled with a gate electrode and a shielded gate electrode, wherein the shielded gate electrode is insulated from the epitaxial layer by a first insulating film, the gate electrode is insulated from the epitaxial layer by a gate oxide, the shielded gate electrode and the gate electrode is insulated from each other by an IPO film, an OCB region is formed between two adjacent gate trenches below the body regions and above a bottom of the shielded gate electrode; a short channel implant region is formed along upper sidewalls of the gate trenches and surrounds the gate electrode; a buffer region of the first conductivity type is formed between the substrate and the OCB region; the body regions, the shielded gate electrode and the source regions are shorted together to a source metal through a plurality of trenched contacts; the epitaxial layer in the OCB region has MSE layers with different doping concentrations decreasing stepwise in a direction from a bottom of the shielded gate electrode toward the body regions along sidewalls of the gate trenches, wherein each of the MSE layers has a uniform doping concentration as grown; and the SGT SJ MOSFET further comprises a SJ region below the OCB region including alternating first doped columns of the first conductivity type and second doped columns of the second conductivity type arranged in parallel wherein each of the second conductivity columns is disposed between two adjacent gate trenches and connected to the body regions; the SJ region between the OCB region and the buffer region has a single epitaxial layer, doping concentrations of the first doped columns are substantially same as doping concentrations of the second doped columns.

According to another aspect, in some preferred embodiments, the gate electrode is not electrically shorted together to a source metal, the SGT device is a MOSFET having a gate electrode, a source electrode and a drain electrode. In some other preferred embodiments, the gate electrode is electrically shorted together to a source metal; the SGT device is a SBR having an anode electrode and a cathode electrode, wherein the source region is electrically connected with the anode electrode and the drain region is electrically connected with the cathode electrode.

According to another aspect, in some preferred embodiments, the gate electrode is disposed above the shielded gate electrode.

According to another aspect, in some preferred embodiments, the epitaxial layer in the OCB region comprises at least two stepped epitaxial layers of different doping concentrations including a bottom epitaxial layer with a doping concentration D1 and a top epitaxial layer above the bottom epitaxial layer with a doping concentration D2, wherein D2<D1. In some other preferred embodiments, the epitaxial layer in the OCB region comprises at least three stepped epitaxial layers of different doping concentration including a bottom epitaxial layer with a doping concentration D1, a middle epitaxial layer with a doping concentration D2 and a top epitaxial layer with doping concentration D3, wherein D3<D2<D1.

According to another aspect, in some preferred embodiments, the first insulating film is a single oxide film having a uniform thickness along sidewalls of the gate trenches.

The invention also features a method for manufacturing a SGT MOSFET having short channel implant regions, comprising: (a) growing an epitaxial layer of a first conductivity type onto a heavily doped substrate with the first conductivity type; (b) applying a hard mask onto a top surface of the epitaxial layer and etching a plurality of gate trenches by the definition of the hard mask; (c) forming a first insulating film by thermal oxide growth and/or thick oxide deposition; (d) depositing a first doped poly-silicon and performing the etching back process to form shielded gate electrodes in the gate trenches; (e) etching back the first insulting film to keep necessary portion surrounding the shielded gate electrodes; (f) performing high density plasma oxide deposition and oxide CMP (Chemical Mechanical Polishing) or wet oxide etching successively to form a second insulating film covering top of the shielded gate electrodes; (g) forming a screen oxide layer covering upper sidewalls of the gate trenches by oxide growth or oxide deposition; (h) performing angle implant of the first conductivity type dopant through the screen oxide layer to form short channel implant regions.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description to explain the principles of the invention. In the drawings:

FIG. 1A is a cross-sectional view of a conventional SGT MOSFET.

FIG. 1B is a cross-sectional view of another conventional SGT MOSFET.

FIG. 1C is a cross-sectional view of a SGT MSO MOSFET of prior art.

FIG. 2A is a cross-sectional view of a preferred embodiment according to the present invention.

FIG. 2B is a cross-sectional view of another preferred embodiment according to the present invention.

FIG. 2C is a cross-sectional view of another preferred embodiment according to the present invention.

FIG. 2D is a cross-sectional view of another preferred embodiment according to the present invention.

FIG. 3A is a cross-sectional view of another preferred embodiment according to the present invention.

FIG. 3B is a cross-sectional view of another preferred embodiment according to the present invention.

FIG. 3C is a cross-sectional view of another preferred embodiment according to the present invention.

FIG. 3D is a cross-sectional view of another preferred embodiment according to the present invention.

FIG. 4A is a cross-sectional view of another preferred embodiment wherein doping concentration variations of the N type epitaxial layer, the N& P columns are depicted along the vertical direction according to the present invention.

FIG. 4B is a cross-sectional view of the preferred embodiment shown in FIG. 4A, wherein doping concentration variations of the N columns and P columns are depicted separately along the vertical direction according to the present invention.

FIG. 5A is a cross-sectional view of another preferred embodiment wherein doping concentration variations of the N type epitaxial layer, the N& P columns are depicted along the vertical direction according to the present invention.

FIG. 5B is a cross-sectional view of the preferred embodiment shown in FIG. 5A, wherein doping concentration variations of the N columns and P columns are depicted separately along the vertical direction according to the present invention.

FIG. 6A is a cross-sectional view of another preferred embodiment according to the present invention.

FIG. 6B is a cross-sectional view of another preferred embodiment according to the present invention.

FIG. 6C is a cross-sectional view of another preferred embodiment according to the present invention.

FIG. 6D is a cross-sectional view of another preferred embodiment according to the present invention.

FIG. 7A is a cross-sectional view of another preferred embodiment according to the present invention.

FIG. 7B is a cross-sectional view of another preferred embodiment according to the present invention.

FIG. 7C is a cross-sectional view of another preferred embodiment according to the present invention.

FIG. 7D is a cross-sectional view of another preferred embodiment according to the present invention.

FIG. 8A is a cross-sectional view of another preferred embodiment wherein doping concentration variations of the N type epitaxial layer, the N& P columns are depicted along the vertical direction according to the present invention.

FIG. 8B is a cross-sectional view of the preferred embodiment shown in FIG. 4A, wherein doping concentration variations of the N columns and P columns are depicted separately along the vertical direction according to the present invention.

FIG. 9A is a cross-sectional view of another preferred embodiment wherein doping concentration variations of the N type epitaxial layer, the N& P columns are depicted along the vertical direction according to the present invention.

FIG. 9B is a cross-sectional view of the preferred embodiment shown in FIG. 5A, wherein doping concentration variations of the N columns and P columns are depicted separately along the vertical direction according to the present invention.

FIGS. 10A˜1OD are a serial of side cross-sectional views for showing the processing steps for fabricating the trench MOSFET of FIG. 2A.

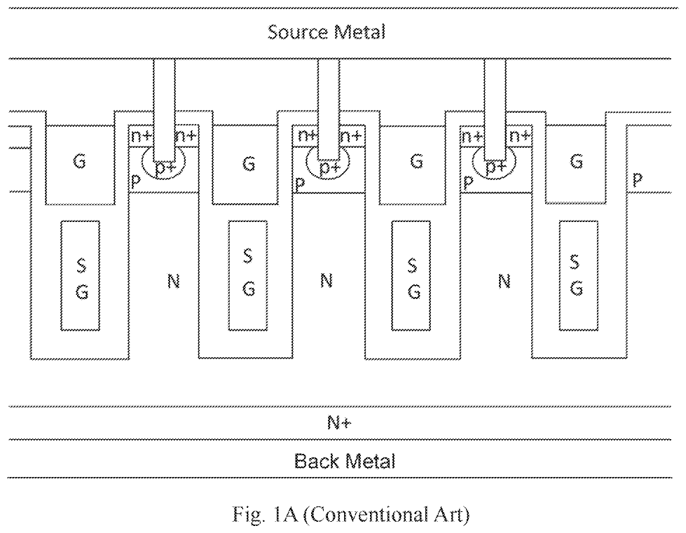

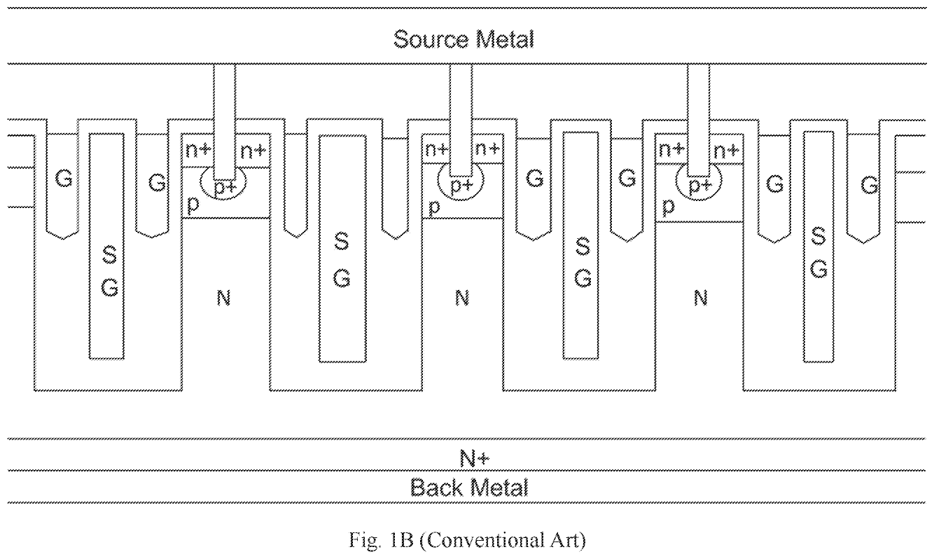

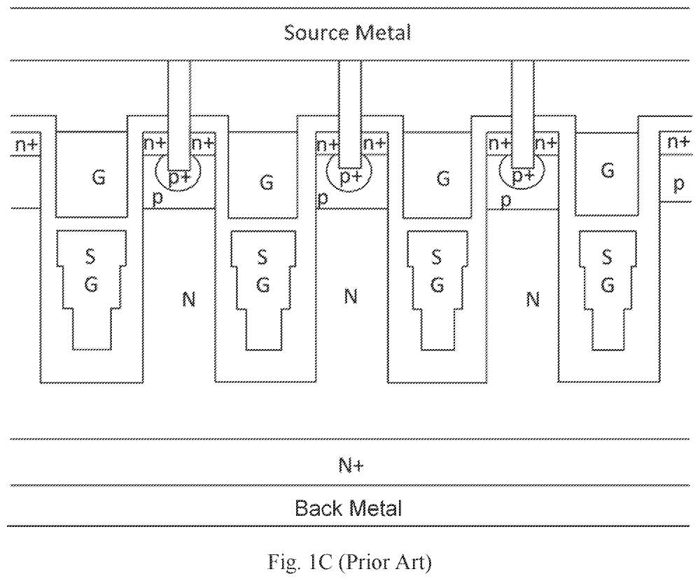

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

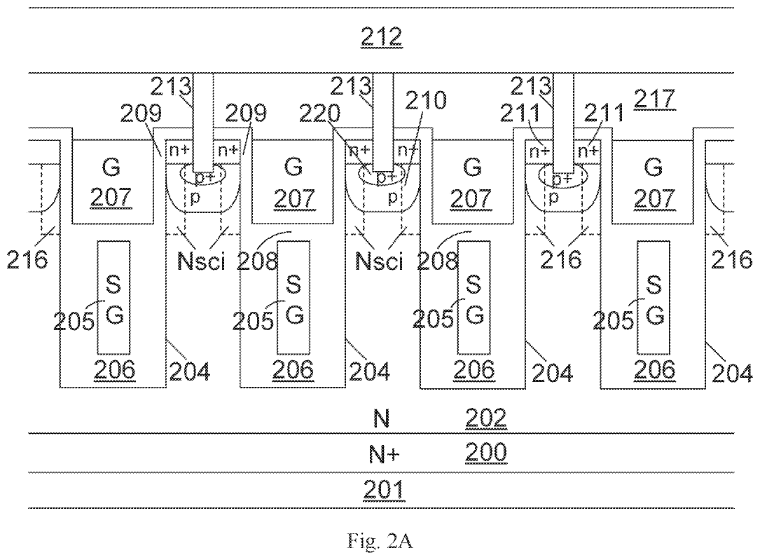

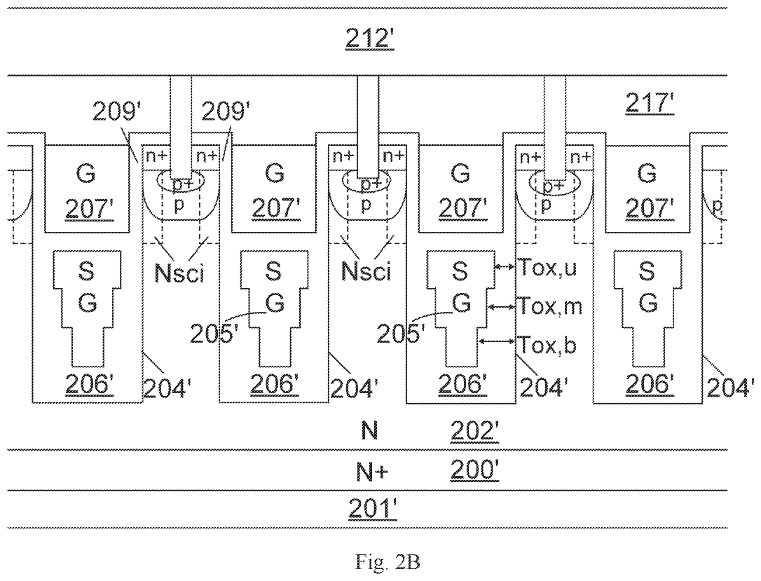

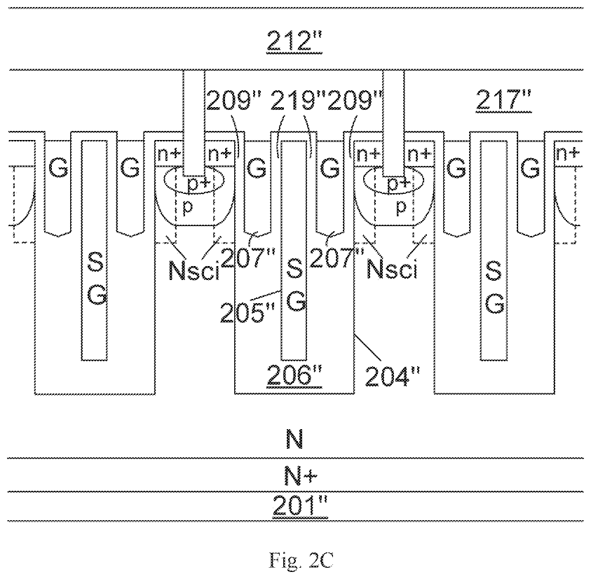

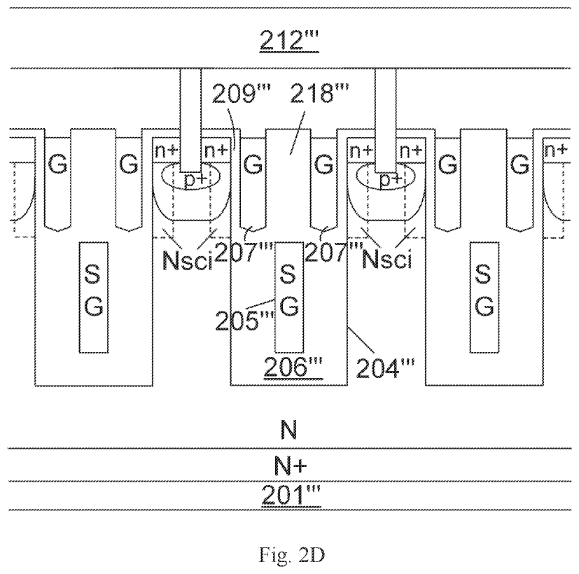

Please refer to FIG. 2A for a preferred embodiment of this invention with new and improved device structure, wherein an N-channel SGT MOSFET is formed in an N type epitaxial layer 202 onto an N+ substrate 200 as a drain region coated with a back metal 201 of Ti/Ni/Ag on rear side as a drain metal. Inside the N epitaxial layer 202, a plurality of gate trenches 204 are formed vertically downward from a top surface of the N type epitaxial layer 202 and not reaching the common interface between the N type epitaxial layer 202 and the N+ substrate 200. Inside each of the gate trenches 204, a shielded gate electrode (SG, as illustrated) 205 is disposed in the lower portion and a single gate electrode (G, as illustrated) 207 is disposed in the upper portion. The shielded gate electrode 205 is insulated from the adjacent epitaxial layer by a first insulating film 206 as a field plate oxide, and the gate electrode 207 is insulated from the adjacent epitaxial layer by a gate oxide 209, wherein the gate oxide 209 has a thinner thickness than the first insulating film 206 which has a uniform thickness along trench sidewalls, meanwhile, the shielded gate electrode 205 and the gate electrode 207 is insulated from each other by a second insulating film 208 as an inter-poly oxide (IPO) layer. Between every two adjacent gate trenches 204, the P body regions 210 with n+ source regions 211 thereon are extending near top surface of the N epitaxial layer 202, and a short channel implant region (illustrated as Nsci) 216 is formed close to the gate oxide 209 along upper sidewalls of the gate trench 204 surrounding the gate electrode 207 to provide a shorter channel length after P body implantation and diffusion, thus reducing the channel resistance. The P body regions 210, the shielded gate electrode 205 and the n+ source regions 211 are further shorted together to a source metal 212 through a plurality of trenched contacts 213 filled with metal contact plugs and barriers implemented by penetrating through a contact insulating layer 217 and surrounded by p+ heavily doped regions 220 around bottoms underneath the n+ source regions 211. According to the invention, an OCB region is therefore formed in a mesa area between the adjacent gate trenches 204.

Please refer to FIG. 2B for another preferred embodiment of the present invention with new and improved device structure. The N-channel trenched semiconductor power device has a similar device structure to FIG. 2A, except that, in FIG. 2B, the first insulating film 206′ in the gate trenches 204′ has three stepped oxide structure having a lower portion oxide along lower portion sidewalls and bottom of the gate trenches 204′ with a uniform first thickness Tox,b, a middle portion oxide with a uniform second thickness Tox,m, and an upper portion oxide with a uniform third thickness Tox,u, where Tox,b is greater than Tox,m, and Tox,m is greater than Tox,u, to further reduce the on-resistance while maintaining the same breakdown voltage. The Tox,m can be an average of Tox,b and Tox,u.

Please refer to FIG. 2C for another preferred embodiment of the present invention with new and improved device structure. The N-channel trenched semiconductor power device has a similar device structure to FIG. 2A, except for the different shielded gate structure in the gate trenches 204″. Inside each of the gate trenches 204″, a shielded gate electrode (SG, as illustrated) 205″ is disposed in the middle and a pair of split gate electrodes (G, as illustrated) 207″ are disposed surrounding upper portions of the shielded electrode 205″. The second insulating film 219″ isolating the shielded gate electrode 205″ and the gate electrode 207″ is covering on upper portion of the shielded gate electrode 205″, wherein the second insulating film 219″ is formed at the same time during growing the gate oxide 209″ in a manufacturing process.

Please refer to FIG. 2D for another preferred embodiment of the present invention with new and improved device structure. The N-channel trenched semiconductor power device has a similar device structure to FIG. 2C, except that, inside each of the gate trenches 204′″, the upper portion of the shielded gate electrode 205′″ is fully oxidized as the second insulating film 218′″ when the shielded gate electrode is thin enough. Thus, the split gate electrodes 207′″ are insulated from each other by the second insulating film 218′″.

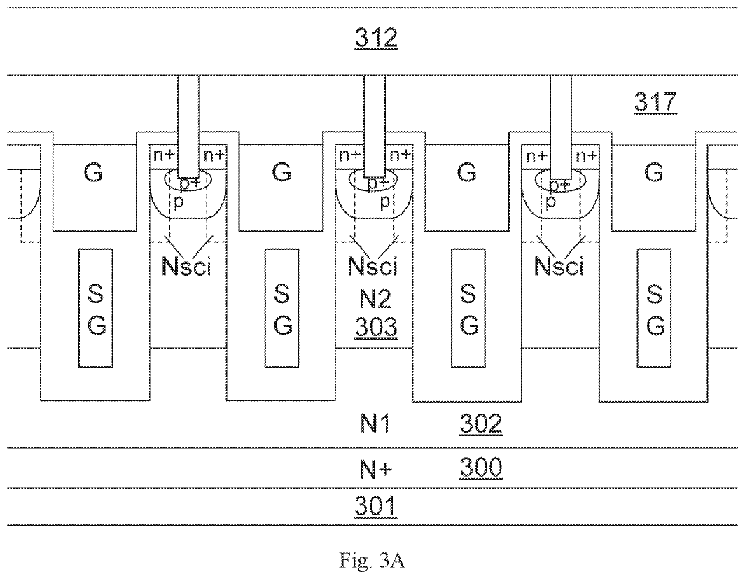

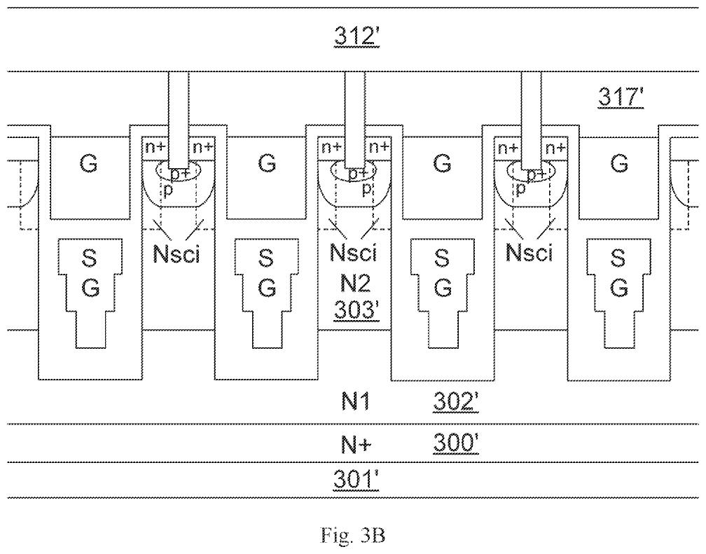

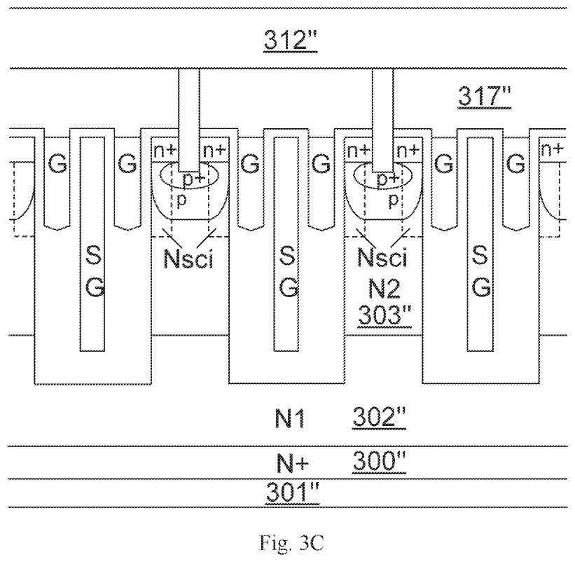

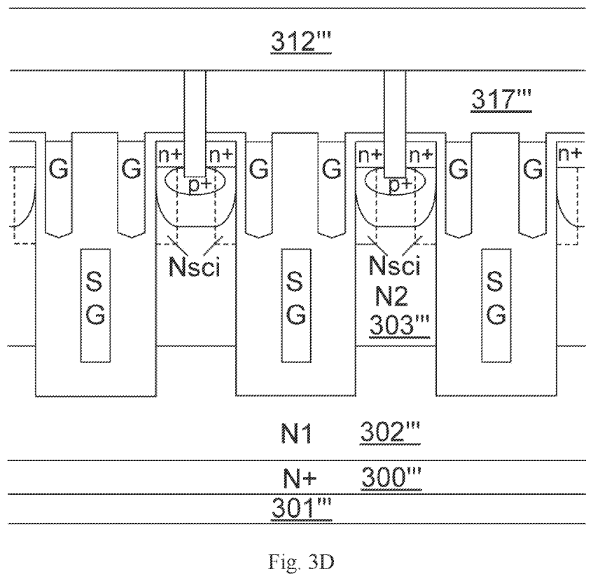

Please refer to FIG. 3A for another preferred embodiment of the present invention with new and improved device structure. The N-channel trenched semiconductor power device has a similar device structure to FIG. 2A, except that the N type epitaxial layer has multiple stepped epitaxial (MSE) layers with different doping concentrations decreasing stepwise in a direction from a substrate to a top surface of the epitaxial layer. In this invention, the N type epitaxial layer comprises a bottom first epitaxial layer (N1, as illustrated) 302 with a doping concentration D1 and a top second epitaxial layer (N2, as illustrated) 303 above the bottom first epitaxial layer 302 with a doping concentration D2, wherein D2<D1, to increase the breakdown voltage and lower the specific on-resistance.

Please refer to FIG. 3B for another preferred embodiment of the present invention with new and improved device structure. The N-channel trenched semiconductor power device has a similar device structure to FIG. 2B, except that the N type epitaxial layer has multiple stepped epitaxial (MSE) layers with different doping concentrations decreasing stepwise in a direction from a substrate to a top surface of the N type epitaxial layer. In this invention, the N type epitaxial layer comprises a bottom first epitaxial layer (N1, as illustrated) 302′ with a doping concentration D1 and a top second epitaxial layer (N2, as illustrated) 303′ above the bottom first epitaxial layer 302 with a doping concentration D2, wherein D2<D1, to increase the breakdown voltage and lower the specific on-resistance.

Please refer to FIG. 3C for another preferred embodiment of the present invention with new and improved device structure. The N-channel trenched semiconductor power device has a similar device structure to FIG. 2C, except that the N type epitaxial layer has multiple stepped epitaxial (MSE) layers with different doping concentrations decreasing stepwise in a direction from a substrate to a top surface of the N type epitaxial layer. In this invention, the N type epitaxial layer comprises a bottom first epitaxial layer (N1, as illustrated) 302″ with a doping concentration D1 and a top second epitaxial layer (N2, as illustrated) 303″ above the bottom first epitaxial layer 302 with a doping concentration D2, wherein D2<D1, to increase the breakdown voltage and lower the specific on-resistance.

Please refer to FIG. 3D for another preferred embodiment of the present invention with new and improved device structure. The N-channel trenched semiconductor power device has a similar device structure to FIG. 2C, except that the N type epitaxial layer has multiple stepped epitaxial (MSE) layers with different doping concentrations decreasing stepwise in a direction from a substrate to a top surface of the N type epitaxial layer. In this invention, the N type epitaxial layer comprises a bottom first epitaxial layer (N1, as illustrated) 302′″ with a doping concentration D1 and a top second epitaxial layer (N2, as illustrated) 303′″ above the bottom first epitaxial layer 302′″ with a doping concentration D2, wherein D2<D1, to increase the breakdown voltage and lower the specific on-resistance.

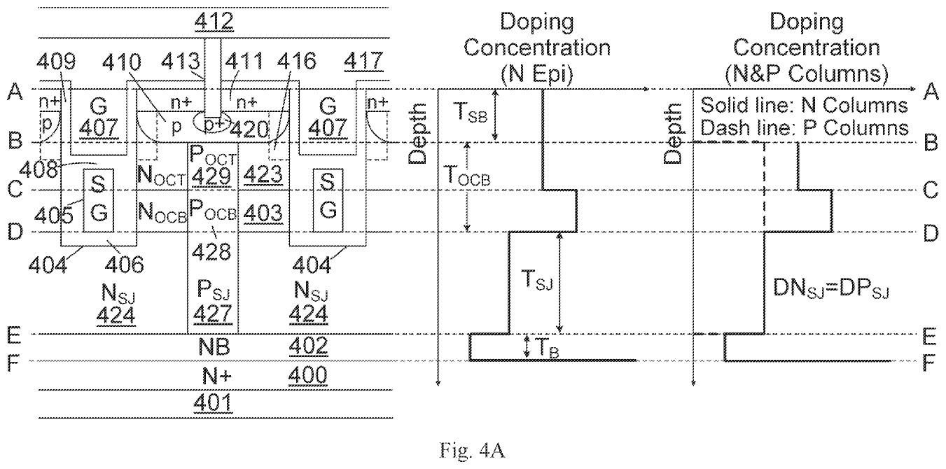

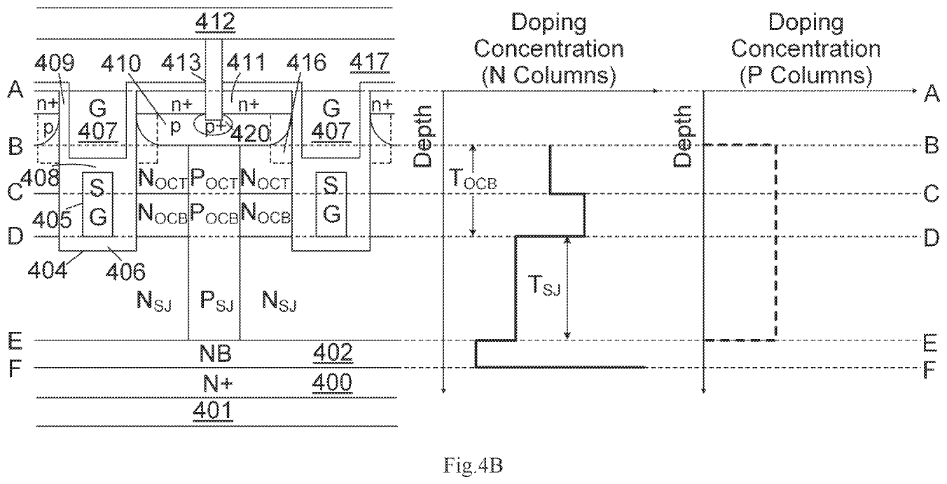

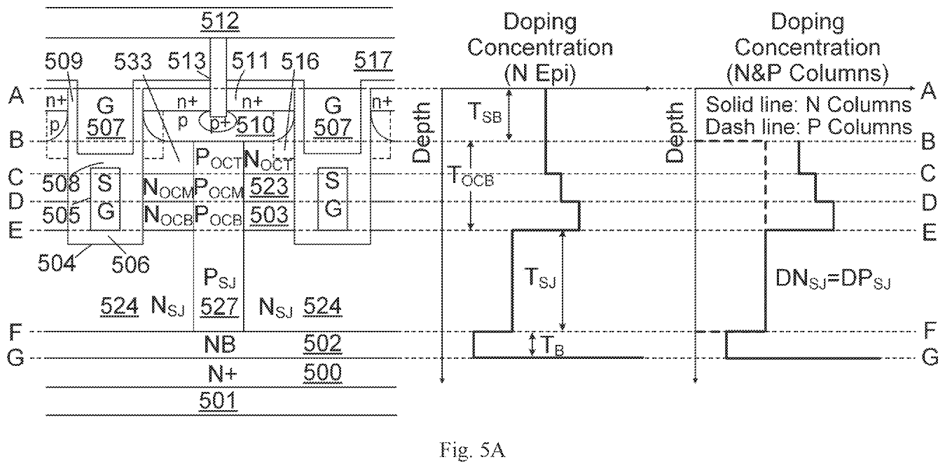

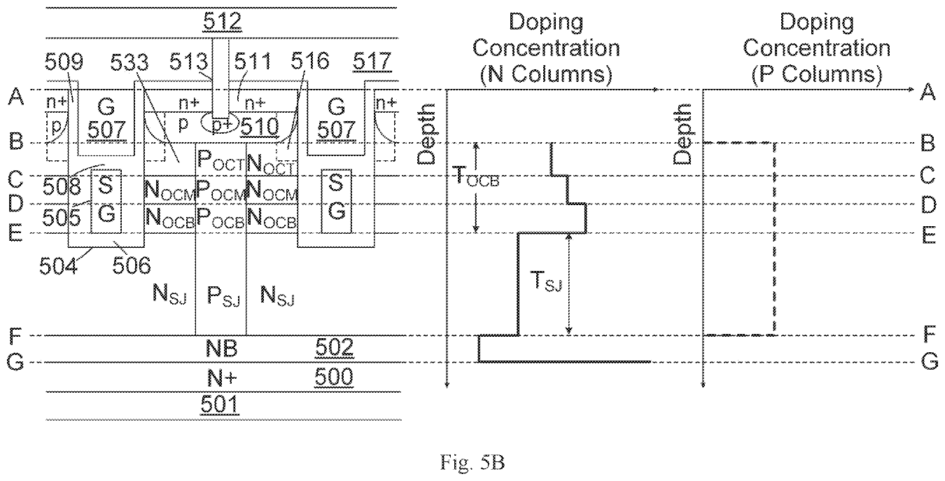

Please refer to FIG. 4A for another preferred embodiment of this invention with new and improved device structure wherein the doping concentration variations of the N type epitaxial layer, the N& P columns as grown are depicted along the vertical direction. The device comprises an N-channel SGT SJ MOSFET formed in an N type epitaxial layer onto an N+ substrate 400 coated with a back metal 401 of Ti/Ni/Ag on rear side as a drain metal. An OCB region T_{OCB} (between B-B and D-D lines) is formed between two adjacent gate trenches 404 below the body regions 410 and above a bottom of the shielded gate electrode 405. The epitaxial layer in the OCB region has MSE layers with two different doping concentrations, including a bottom 1^{st} epitaxial layer (N_{OCB}, as illustrated between C-C and D-D lines) 403 with a doping concentration D1 and a top 2^{nd} epitaxial layer (N_{OCT}, as illustrated between B-B and C-C lines) 423 above the bottom 1^{st} epitaxial layer 403 with a doping concentration D2, wherein D2<D1, to increase the breakdown voltage and lower the specific on-resistance. A SJ region T_{SJ} (between D-D and E-E lines) is formed between the OCB region T_{OCB} and the buffer region 402, including alternating N type doped columns (N_{SJ}, as illustrated) 424 and P type doped columns (Psi, as illustrated) 427 arranged in parallel. The SJ region T_{SJ} has a single epitaxial layer (N_{SJ}, as illustrated) 424 with a uniform doping concentration DN_{SJ}, and doping concentration DN_{SJ} of the single epitaxial layer and N type doped columns 424 is substantially same as doping concentrations DP_{SJ} of the P type doped columns 427 (DN_{SJ}=DP_{SJ}), and is lower than the doping concentration D2 of the top 2^{nd} epitaxial layer 423 in the OCB region. A buffer region T_{B} (N_{B}, as illustrated between E-E and F-F lines) is formed between the N+ substrate 400 and the SJ region. The epitaxial layer in the buffer region has a doping concentration D_{B} lower than the doping concentration DN_{SJ} of the single epitaxial layer 424 in the SJ region. Moreover, widths of P type doped columns (P_{OCB} and P_{OCT}, as illustrated) 428 and 429 in the OCB region between two adjacent gate trenches 404 are equal to widths of the P type doped columns 427 in the SJ region, and all the P type doped columns 428, 429 and 427 have the same doping concentration DP_{SJ}, which is lower than the doping concentration D2 of the top 2^{nd} epitaxial layer 423 in the OCB region. The P type doped columns 427 is connected to the body regions 410 through the P type doped columns 428 and 429. Inside the N type epitaxial layer, a plurality of gate trenches 404 are formed extending from a top surface of the top 2^{nd} epitaxial layer 423 in the OCB region T_{OCB} and vertically downward into the single epitaxial layer 424 in the SJ region, wherein trench bottoms of the gate trenches 404 are above a common interface between the buffer region 402 and the SJ region. Inside each of the gate trenches 404, a shielded gate electrode (SG, as illustrated) 405 is disposed in the lower portion and a single gate electrode (G, as illustrated) 407 is disposed in the upper portion above the shielded gate electrode 405. The shielded gate electrode 405 is insulated from the adjacent epitaxial layer by a first insulating film 406, and the gate electrode 407 is insulated from the adjacent epitaxial layer by a gate oxide 409, wherein the gate oxide 409 has a thinner thickness than the first insulating film 406 which has a uniform thickness along trench sidewalls, meanwhile, the shielded gate electrode 405 and the gate electrode 407 is insulated from each other by an IPO film 408. Between every two adjacent gate trenches 404, the P body regions 410 with n+ source regions 411 thereon are extending near top surface of the top 2^{nd} epitaxial layer 423 in the OCB region to form source regions and body regions T_{SB} between A-A and B-B lines. The epitaxial layer in the source and body regions T_{SB} has a doping concentration same as the top 2^{nd} epitaxial layer 423 in the OCB region. A short channel implant region 416 is formed close to the gate oxide 409 along upper sidewalls of the gate trenches 404 surrounding the gate electrode 407 to provide a shorter channel length after P body implantation and diffusion, thus reducing the channel resistance. The P body regions 410, the n+ source regions 411 and the shielded gate electrodes 405 are further shorted together to a source metal 412 through a plurality of trenched contacts 413 filled with metal contact plugs and barriers implemented by penetrating through a contact insulating layer 417 and surrounded by p+ heavily doped regions 420 around bottoms underneath the n+ source regions 411.

Please refer to FIG. 4B for the same preferred embodiment of the present invention shown in FIG. 4A, wherein doping concentration variations of the N columns and P columns are depicted separately along the vertical direction according to the present invention.

Please refer to FIG. 5A for another preferred embodiment of this invention with new and improved device structure wherein the doping concentration variations of the N type epitaxial layer, the N& P columns as grown are depicted along the vertical direction. The N-channel trenched semiconductor power device has a similar structure to FIG. 4A, except that, in FIG. 5A, the N type epitaxial layer in the OCB region T_{OCB} (between B-B and E-E lines) comprises three stepped epitaxial layers of different doping concentrations including a bottom 1^{st} epitaxial layer (N_{OCB}, as illustrated between D-D and E-E lines) 503 with a doping concentration D1, a middle 2^{nd} epitaxial layer (NO_{CM}, as illustrated between C-C and D-D lines) 523 with a doping concentration D2 and a top 3^{rd} epitaxial layer (N_{OCT}, as illustrated between B-B and C-C lines) 533 with a doping concentration D3, wherein D3<D2<D1, to further reduce the specific on-resistance. The D2 can be an average of D1 and D3. The epitaxial layer in the source and body regions T_{SB} has a doping concentration same as the top 3^{rd} epitaxial layer 533 in the OCB region, which is higher than the doping concentration DN_{SJ} of the single epitaxial layer and N type doped columns (N_{SJ}, as illustrated) 524 in the SJ region. Moreover, all the P type doped columns, including P_{OCT}, P_{OCM} and P_{OCB} in the OCB region and Psi in the SJ region have the same doping concentration DP_{SJ}, which is same as the doping concentration DN_{SJ} of the single epitaxial layer and N type doped columns 524 in the SJ region and lower than the doping concentration D3 of the top 3rd epitaxial layer 533 in the OCB region.

Please refer to FIG. 5B for the same preferred embodiment of the present invention shown in FIG. 5A, wherein doping concentration variations of the N columns and P columns are depicted separately along the vertical direction according to the present invention.

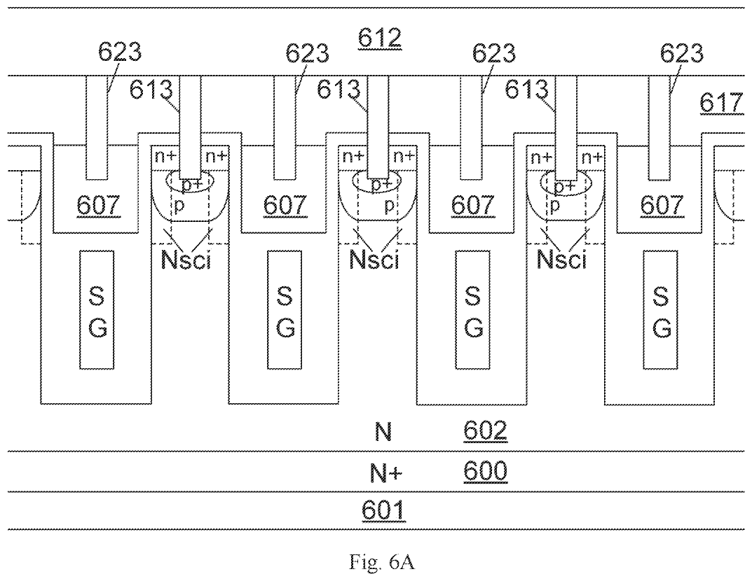

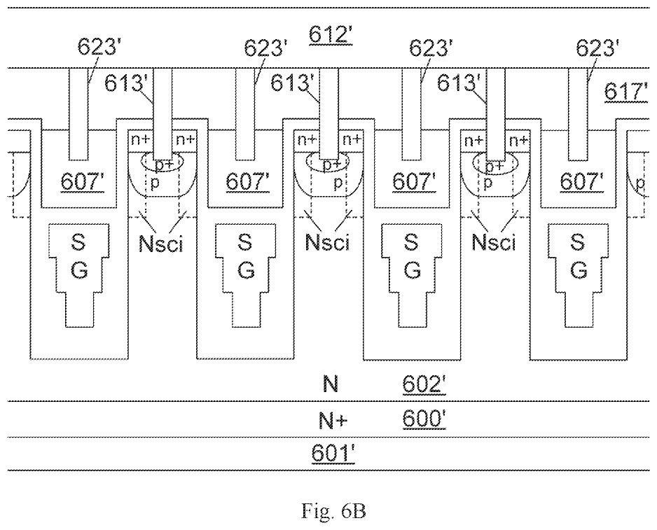

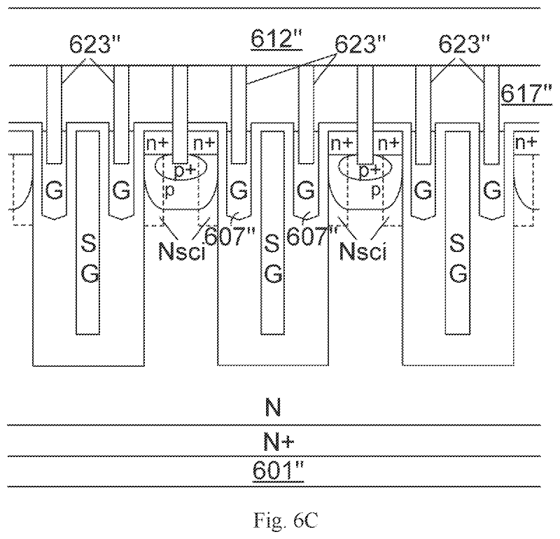

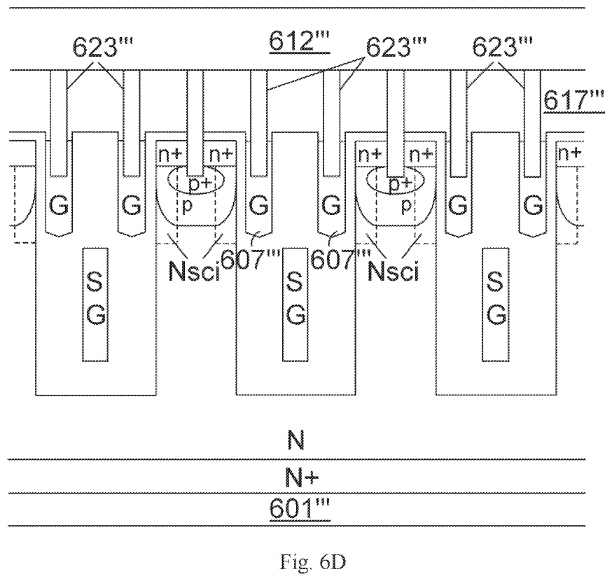

Please refer to FIG. 6A for another preferred embodiment of the present invention representing a SGT SBR device with single epitaxial layer. The N-channel trenched semiconductor power device has a similar device structure to FIG. 2A, except that, in this invention, the gate electrodes 607 are electrically shorted together to a source metal 612 by a plurality of trenched contacts 623 filled with metal contact plugs and barriers, which are implemented by penetrating through a contact insulating layer 617 and extending into the gate electrodes 607. The SGT SBR device has the source metal 612 as anode electrode and a back metal 601 as cathode electrode.

Please refer to FIG. 6B for another preferred embodiment of the present invention representing a SGT SBR device with a single epitaxial layer. The N-channel trenched semiconductor power device has a similar device structure to FIG. 2B, except that, in this invention, the gate electrodes 607′ are electrically shorted together to a source metal 612′ by a plurality of trenched contacts 623′ filled with metal contact plugs and barriers, which are implemented by penetrating through a contact insulating layer 617′ and extending into the gate electrodes 607′.

Please refer to FIG. 6C for another preferred embodiment of the present invention representing a SGT SBR device with single epitaxial layer. The N-channel trenched semiconductor power device has a similar device structure to FIG. 2C, except that, in this invention, the gate electrodes 607″ are electrically shorted together to a source metal 612″ by a plurality of trenched contacts 623″ filled with metal contact plugs and barriers, which are implemented by penetrating through a contact insulating layer 617″ and extending into the gate electrodes 607″.

Please refer to FIG. 6D for another preferred embodiment of the present invention representing a SGT SBR device with single epitaxial layer. The N-channel trenched semiconductor power device has a similar device structure to FIG. 2D, except that, in this invention, the gate electrodes 607′″ are electrically shorted together to a source metal 612′″ by a plurality of trenched contacts 623′″ filled with metal contact plugs and barriers, which are implemented by penetrating through a contact insulating layer 617′″ and extending into the gate electrodes 607′″.

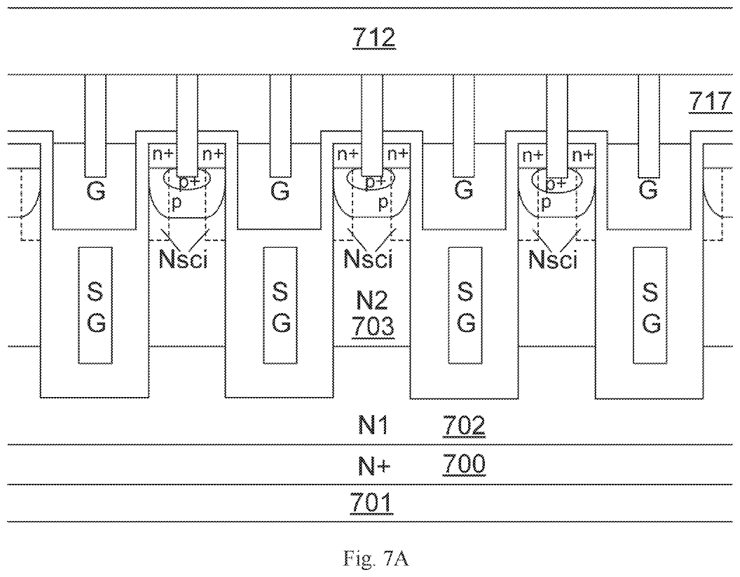

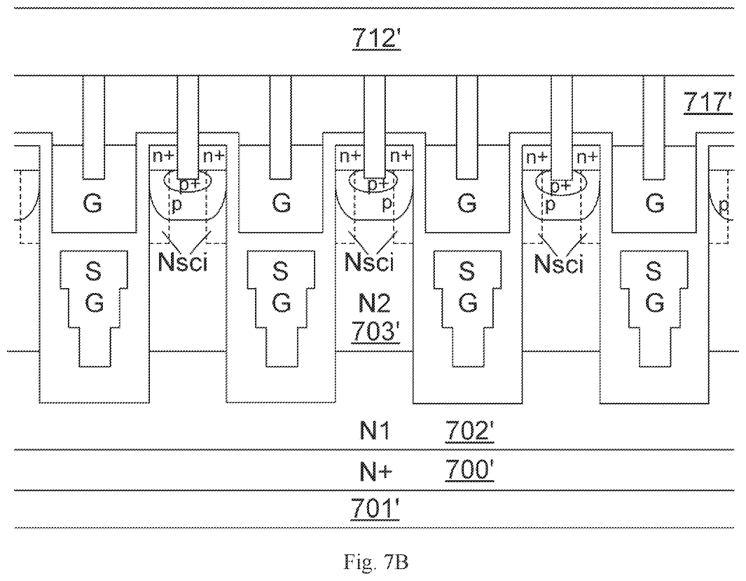

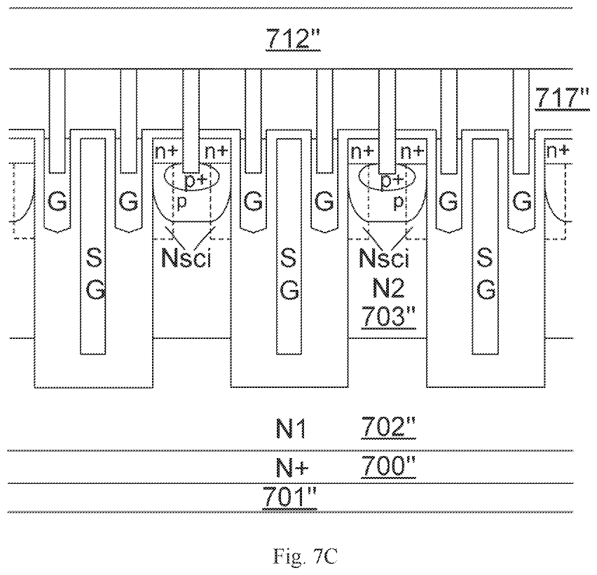

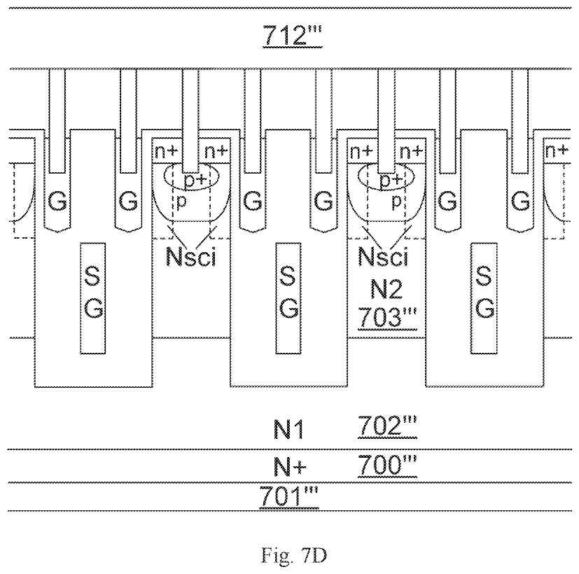

Please refer to FIG. 7A for another preferred embodiment of the present invention representing a SGT SBR device with two stepped epitaxial layers. The N-channel trenched semiconductor power device has a similar device structure to FIG. 6A, except for the different epitaxial layers. In this invention, the N type epitaxial layer comprises a bottom first epitaxial layer (N1, as illustrated) 702 with a doping concentration D1 and a top second epitaxial layer (N2, as illustrated) 703 above the bottom first epitaxial layer 702 with a doping concentration D2, wherein D2<D1, to increase the breakdown voltage and lower the specific on-resistance.

Please refer to FIG. 7B for another preferred embodiment of the present invention representing a SGT SBR device with two stepped epitaxial layers. The N-channel trenched semiconductor power device has a similar device structure to FIG. 6B, except for the different epitaxial layers. In this invention, the N type epitaxial layer comprises a bottom first epitaxial layer (N1, as illustrated) 702′ with a doping concentration D1 and a top second epitaxial layer (N2, as illustrated) 703′ above the bottom first epitaxial layer 702′ with a doping concentration D2, wherein D2<D1, to increase the breakdown voltage and lower the specific on-resistance.

Please refer to FIG. 7C for another preferred embodiment of the present invention representing a SGT SBR device with two stepped epitaxial layers. The N-channel trenched semiconductor power device has a similar device structure to FIG. 6C, except for the different epitaxial layers. In this invention, the N type epitaxial layer comprises a bottom first epitaxial layer (N1, as illustrated) 702″ with a doping concentration D1 and a top second epitaxial layer (N2, as illustrated) 703″ above the bottom first epitaxial layer 702″ with a doping concentration D2, wherein D2<D1, to increase the breakdown voltage and lower the specific on-resistance.

Please refer to FIG. 7D for another preferred embodiment of the present invention representing a SGT SBR device with two stepped epitaxial layers. The N-channel trenched semiconductor power device has a similar device structure to FIG. 6D, except for the different epitaxial layers. In this invention, the N type epitaxial layer comprises a bottom first epitaxial layer (N1, as illustrated) 702′″ with a doping concentration D1 and a top second epitaxial layer (N2, as illustrated) 703′″ above the bottom first epitaxial layer 702′″ with a doping concentration D2, wherein D2<D1, to increase the breakdown voltage and lower the specific on-resistance.

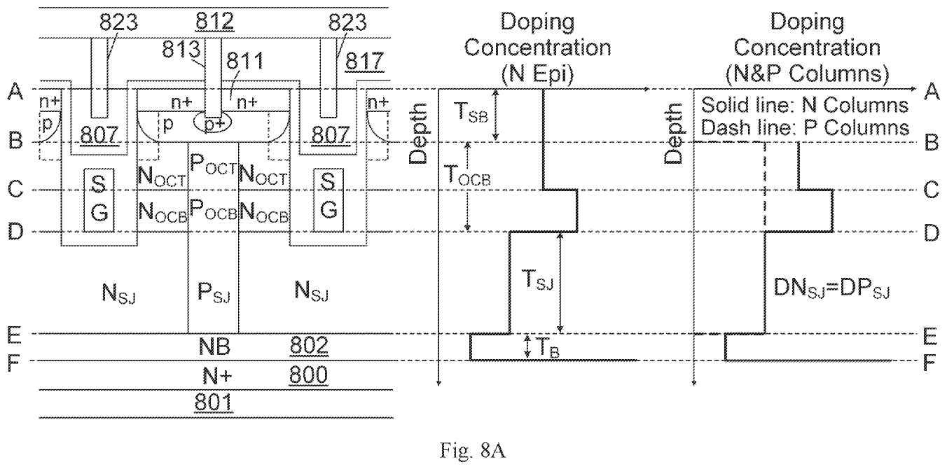

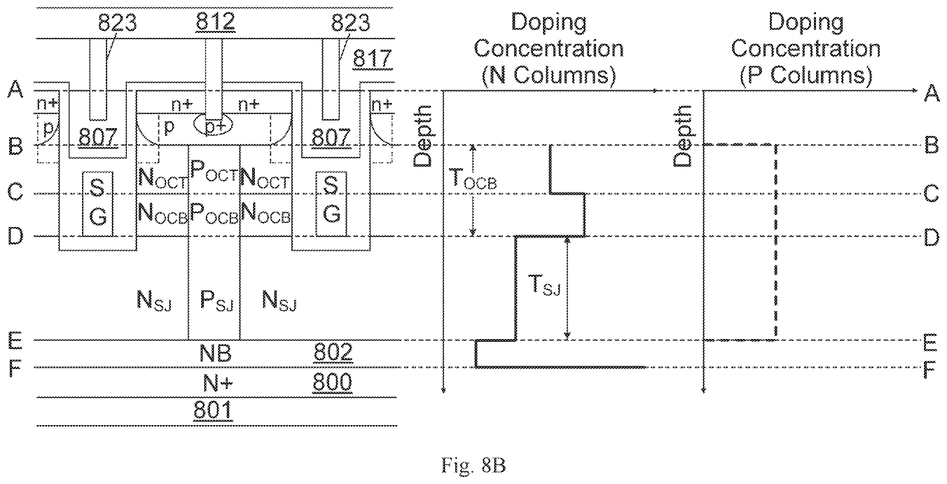

Please refer to FIG. 8A for another preferred embodiment of this invention with new and improved device structure wherein the doping concentration variations of the N type epitaxial layer, the N& P columns as grown are depicted along the vertical direction. The N-channel trenched semiconductor power device has a similar device structure to FIG. 4A, except that, in this invention, the gate electrodes 807 are electrically shorted together to a source metal 812 by a plurality of trenched contacts 823 filled with metal contact plugs and barriers, which are implemented by penetrating through a contact insulating layer 817 and extending into the gate electrodes 807.

Please refer to FIG. 8B for the same preferred embodiment of the present invention shown in FIG. 8A, wherein doping concentration variations of the N columns and P columns are depicted separately along the vertical direction according to the present invention.

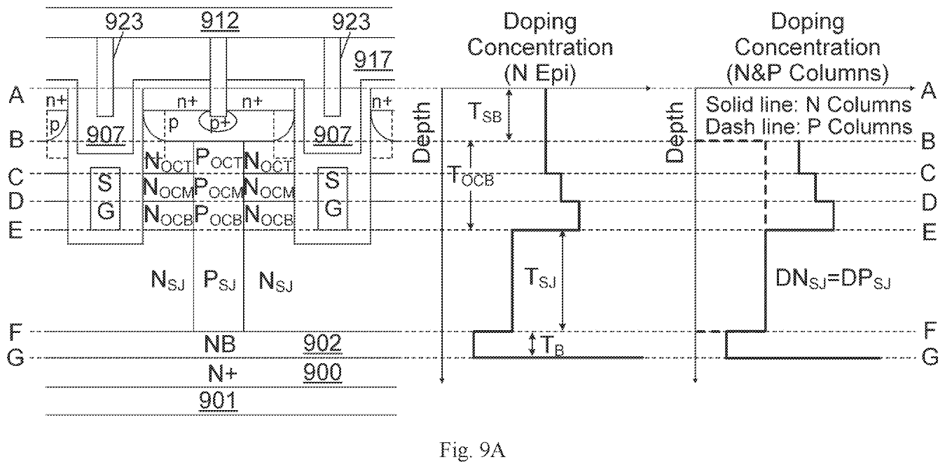

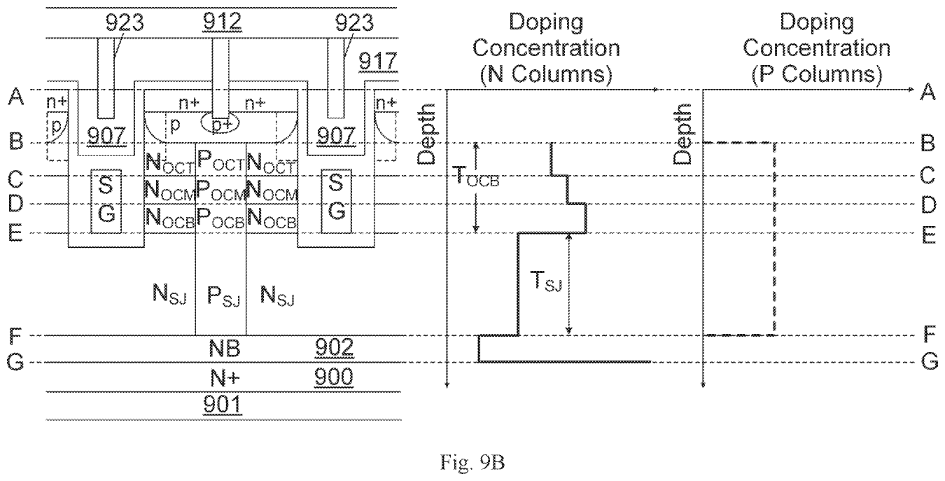

Please refer to FIG. 9A for another preferred embodiment of this invention with new and improved device structure wherein the doping concentration variations of the N type epitaxial layer, the N& P columns as grown are depicted along the vertical direction. The N-channel trenched semiconductor power device has a similar device structure to FIG. 5A, except that, in this invention, the gate electrodes 907 are electrically shorted together to a source metal 912 by a plurality of trenched contacts 923 filled with metal contact plugs and barriers, which are implemented by penetrating through a contact insulating layer 917 and extending into the gate electrodes 907.

Please refer to FIG. 9B for the same preferred embodiment of the present invention shown in FIG. 9A, wherein doping concentration variations of the N columns and P columns are depicted separately along the vertical direction according to the present invention.

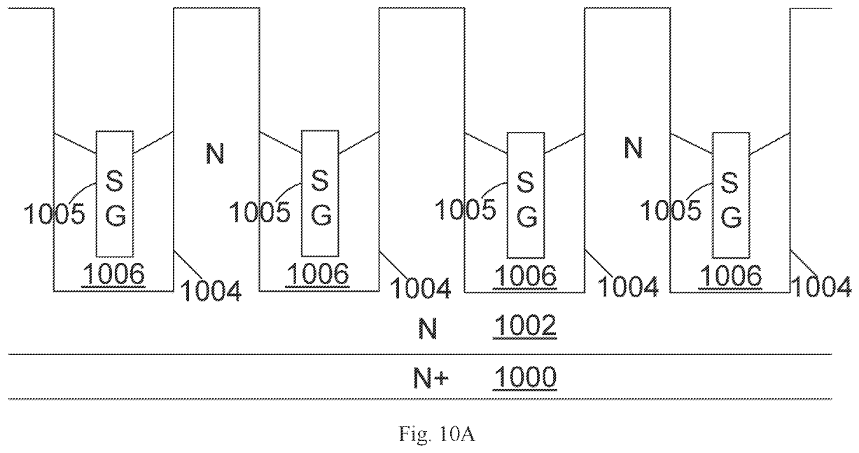

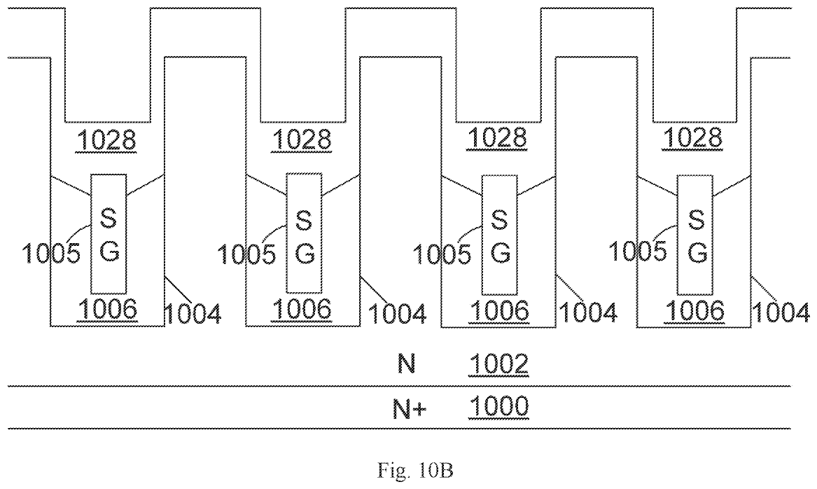

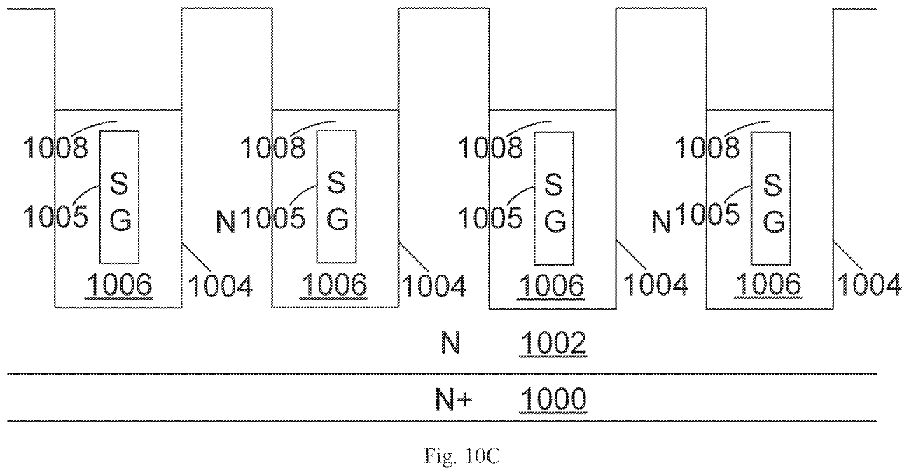

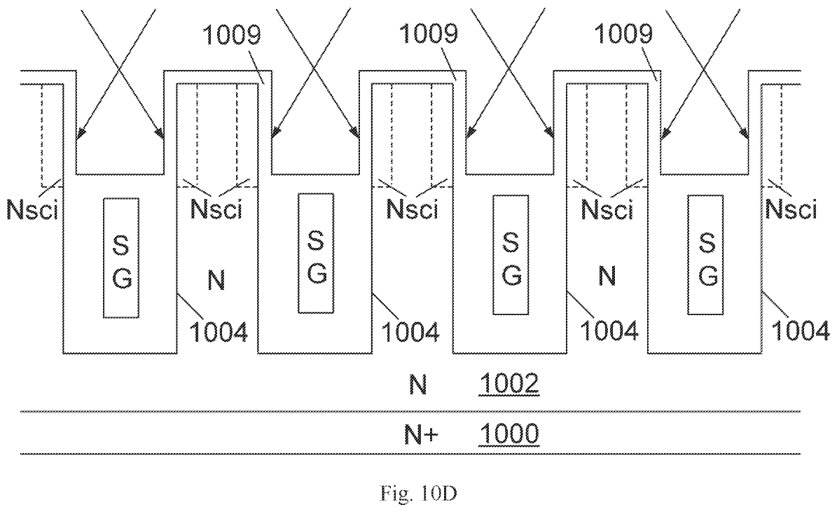

FIGS. 10A˜10D are a serial of exemplary steps that are performed to form the invented short channel implant region according to the embodiment of FIG. 2A. In FIG. 10A, an N epitaxial layer 1002 is grown on an N+ substrate 1000, a hard mask (not shown) such as an oxide layer is applied onto a top surface of the N epitaxial layer 1002 for definition of areas for a plurality of gate trenches. Then, after dry oxide etch and dry silicon etch, a plurality of gate trenches 1004 are etched penetrating through open regions in the hard mask and down into the N epitaxial layer 1002, not reaching the bottom surface of N epitaxial layer 1002. Mesas are thus formed between every two adjacent gate trenches 1004 in the N epitaxial layer 1002. Then, a sacrificial oxide layer (not shown) is first grown and then removed to eliminate the plasma damage after forming the gate trenches 1004. The hard mask is removed, and a first gate insulation layer 1006 comprising a thick oxide layer is formed lining the inner surface of the gate trenches 1004 by thermal oxide growth and/or thick oxide deposition. Then, a first doped poly-silicon layer is deposited onto the first gate insulation layer 1006 to fill the gate trenches 1004, and is then etched back from the top surface of the N epitaxial layer 1002 to remain in lower portion of the gate trenches 1004 to serve as the shielded gate electrode 1005. Next, the first gate insulation layer 1006 is etched back from top surface of the epitaxial layer and an upper portion of the gate trenches 1004 to insulate the shielded gate electrodes 1005 from the adjacent N epitaxial layer 1002.

In FIG. 10B, another gate insulation layer 1028 is formed by a high density plasma oxide deposition along upper inner surfaces of the gate trenches 1004, covering a top surface of the first gate insulation layer 1006, the shielded gate electrode 1005 and the N epitaxy layer 1002.

In FIG. 10C, the gate insulation layer 1028 is etched back by oxide CMP (Chemical Mechanical Polishing) or by wet oxide etching to leave a thick layer 1008 covering top of the shielded gate electrodes 1005 and the first insulating film 1006 within the gate trenches 1004 as an inter-poly oxide (IPO) layer 1008 likes the IPO layer 208 as shown in FIG. 2A.

In FIG. 10D, a screen oxide layer 1009 is grown or deposited covering upper inner surfaces of the gate trenches 1004 and top surface of epitaxy layer 1002 for the following implantation. Then, a step of arsenic or phosphorus angle implant is performed to form the short channel implant (illustrate as Nsci) region through the screen oxide layer 1009.

For all the described preferred embodiment, the first type conductivity type is N type and the second conductivity type is P type, the opposite is also applicable to the present invention when the first type is P type and the first type is N type.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A shielded gate trench (SGT) device formed in an epitaxial layer of a first conductivity type on a substrate of said first conductivity type as a drain region coated with a back metal, further comprising:
a plurality of gate trenches surrounded by source regions of said first conductivity type being encompassed in body regions of a second conductivity type, each of said gate trenches being filled with a gate electrode and a shielded gate electrode; said shielded gate electrode being insulated from said epitaxial layer by a first insulating film, said gate electrode being insulated from said epitaxial layer by a gate oxide, said shielded gate electrode and said gate electrode being insulated from each other by an (Inter-Poly Oxide) IPO film, said gate oxide surrounding said gate electrode and having a less thickness than said first insulating film;
said body regions, said shielded gate electrode and said source regions being shorted together to a source metal; and
a short channel implant region of said first conductivity type formed along upper trench sidewalls of said gate trenches and surrounding said gate electrode.

2. The SGT device of claim 1, wherein said epitaxial layer is a single epitaxial layer with an uniform doping concentration.

3. The SGT device of claim 1, wherein said epitaxial layer has multiple stepped epitaxial (MSE) layers with different doping concentrations decreasing stepwise in a direction from said substrate to a top surface of said epitaxial layer, wherein each of said MSE layers has an uniform doping concentration as grown.

4. The SGT device of claim 1, wherein said gate electrode is not electrically shorted together to said source metal, said SGT device is a MOSFET having said gate electrode, said source metal as a source electrode and said back metal as a drain electrode.

5. The SGT device of claim 1, wherein said gate electrode is electrically shorted together to said source metal; said SGT device is a super barrier rectifier (SBR) having an anode electrode and a cathode electrode, wherein said source metal acts as said anode electrode and said back metal acts as said cathode electrode.

6. The SGT device of claim 1, wherein said gate electrode is disposed above said shielded gate electrode.

7. The SGT device of claim 1, wherein said shielded electrode is disposed in the middle of said gate trenches and said gate electrode is disposed surrounding upper portion of said shielded electrode.

8. The SGT device of claim 7, wherein said upper portion of said shielded gate electrode is fully oxidized as a second insulating film during growing said gate oxide.

9. The SGT device of claim 3, wherein said epitaxial layer comprises at least two stepped epitaxial layers of different doping concentrations including a bottom epitaxial layer with a doping concentration D1 and a top epitaxial layer above said bottom epitaxial layer with a doping concentration D2, wherein said D2<said D1.

10. The SGT device of claim 1, wherein said first insulating film is a single oxide film having an uniform thickness along sidewalls of said gate trenches.

11. The SGT device of claim 1, wherein said first insulating film has multiple stepped oxides (MSO) structure with different thicknesses along trench sidewalls of said gate trenches decreasing stepwise in a direction from said substrate to said body regions.

12. The SGT device of claim 1, wherein said short channel implant region is formed by performing an angle implant of a dopant of said first conductivity type into upper trench sidewalls of said gate trenches.

13. A shielded gate trench (SGT) super junction (SJ) device formed in an epitaxial layer of a first conductivity type on a substrate of said first conductivity type as a drain region coated with a back metal, comprising:
a plurality of gate trenches formed in an active area, surrounded by source regions of said first conductivity type are encompassed in body regions of a second conductivity type, each of said gate trenches is filled with a gate electrode and a shielded gate electrode; said shielded gate electrode is insulated from said epitaxial layer by a first insulating film, said gate electrode is insulated from said epitaxial layer by a gate oxide, said shielded gate electrode and said gate electrode are insulated from each other by an Inter-Poly Oxide (IPO) film, said gate oxide surrounds said gate electrode and has less thickness than said first insulating film;
an oxide charge balance (OCB) region of said first conductivity type formed in a mesa region between two adjacent said gate trenches below said body regions and above a bottom of said shielded gate electrode;
a short channel implant region of said first conductivity type formed along upper trench sidewalls of said gate trenches and surrounding said gate electrode;
a buffer region of said first conductivity type formed between said substrate and said OCB region;
said body regions, said shielded gate electrode and said source regions are shorted together to a source metal;
said epitaxial layer in said OCB region has multiple stepped epitaxial (MSE) layers with different doping concentrations decreasing stepwise in a direction from a bottom of said shielded gate electrode toward said body regions along sidewalls of said gate trenches, wherein each of said MSE layers has an uniform doping concentration as grown; and
said SGT SJ MOSFET further comprising a SJ region below the OCB region including alternating first doped columns of said first conductivity type and second doped columns of said second conductivity type arranged in parallel wherein each of said second columns is disposed between two adjacent said gate trenches and connected to said body regions.

14. The SGT device of claim 13, wherein said gate electrode is not electrically shorted together to a source metal, said SGT device is a MOSFET having said gate electrode, said source metal as a source electrode and said back metal as a drain electrode.

15. The SGT device of claim 13, wherein said gate electrode is electrically shorted together to a source metal; said SGT device is a super barrier rectifier (SBR) having an anode electrode and a cathode electrode, wherein said source metal acts as said anode electrode and said back metal acts as said cathode electrode.

16. The SGT SJ device of claim 13, wherein said gate electrode is disposed above said shielded gate electrode.

17. The SGT SJ device of claim 13, wherein said epitaxial layer in the OCB region comprises at least two stepped epitaxial layers of different doping concentrations including a bottom epitaxial layer with a doping concentration D1 and a top epitaxial layer above said bottom epitaxial layer with a doping concentration D2, wherein said D2<said D1.

18. The SGT SJ device of claim 13, wherein said epitaxial layer in the OCB region comprises at least three stepped epitaxial layers of different doping concentration including a bottom epitaxial layer with a doping concentration D1, a middle epitaxial layer with a doping concentration D2 and a top epitaxial layer with a doping concentration D3, wherein said D3<said D2<said D1.

19. The SGT SJ device of claim 13, wherein doping concentrations of said first doped columns in said SJ region are substantially same as doping concentrations of said second doped columns.

20. The SGT SJ of claim 13, wherein said short channel implant region is formed by performing an angle implant of a dopant of said first conductivity type into upper trench sidewalls of said gate trenches.
